(19) United States
(12) Patent Application Publication
(10) Pub. No.: US 2021/0278730 A1
(43) Pub. Date: Sep. 9, 2021

(54) DISPLAY DEVICE

(71) Applicant: SHARP KABUSHIKI KAISHA, Sakai City (JP)

(72) Inventor: KAZUMA HIRAO, Sakai City (JP)

(21) Appl. No.: 17/183,776

(22) Filed: Feb. 24, 2021

Related U.S. Application Data
(60) Provisional application No. 62/984,592, filed on Mar. 3, 2020.

(51) Int. Cl. G02F 1/1362; H05K 1/18; G02F 1/1368

(52) U.S. Cl. CPC G02F 1/136272; H05K 1/189; H05K 2201/10136; G02F 1/1368; G02F 1/136286; G02F 1/136254

(57) ABSTRACT

A display device includes a display panel, a flexible printed circuit board having a connection to the display panel by using a film material, a control board having a connection to the flexible printed circuit board by using the film material, and a semiconductor integrated circuit fixed on the display panel by using the film material and functioning as a drive circuit of the display panel. The semiconductor integrated circuit includes an inspection terminal, and the display panel, the flexible printed circuit board, and the control board are provided with an inspection wiring line having one end connected to the inspection terminal and the other end to which a power supply voltage is applied on the control board. The semiconductor integrated circuit includes a built-in resistor and a switching element provided in series between the inspection terminal and a ground, and an abnormality detection circuit that detects an abnormality in a resistance of the connections using the film material based on an output voltage of a resistance dividing circuit constituted by a resistance of the inspection wiring line and the built-in resistor.

### CROSS-REFERENCE TO RELATED APPLICATIONS

This application claims the benefit of priority to U.S. Provisional Application No. 62/984,592 filed on Mar. 3, 2020. The entire contents of the above-identified application are hereby incorporated by reference.

### BACKGROUND

### Technical Field

The disclosure relates to a display device, such as a liquid crystal display device.

Liquid crystal display devices are widely used as thin, lightweight, and low power consumption display devices. In a typical liquid crystal display device, a liquid crystal panel and a control board are connected using a flexible printed circuit board (hereinafter referred to as FPC). The liquid crystal panel and the FPC are connected using an anisotropic conductive film (hereinafter referred to as ACF). The FPC and the control board are also connected using the ACF. A drive circuit IC, which functions as a drive circuit of the liquid crystal panel, is fixed on the liquid crystal panel by using the ACF. Hereinafter, a connection using the ACF is referred to as an ACF connection.

FIG. 4 illustrates a configuration of a known liquid crystal display device. The liquid crystal display device illustrated in FIG. 4 includes a liquid crystal panel 91, an FPC 92, a control board 93, and a drive circuit IC 94. Hatched areas Xa to Xc indicate ACF connections. An image signal VS supplied from a host device (not illustrated) is input to the control board 93 via a connector 95. The image signal VS is input to the drive circuit IC 94 from the control board 93 via the ACF connection Xc, the FPC 92, the ACF connection Xb, the liquid crystal panel 91, and the ACF connection Xa in this order. The image signal VS passes through the three ACF connections Xa to Xc and is input to the drive circuit IC 94.

An abnormality may occur in the ACF connections. An abnormality in the ACF connections may occur, for example, due to poor compression bonding during manufacturing. An abnormality in the ACF connections may also occur as a result of performing environmental tests such as thermal shock tests and high-temperature and high-humidity tests. If an abnormality occurs in the ACF connections, a display defect occurs in the liquid crystal display device. Therefore, as illustrated in FIG. 4, a method of detecting an abnormality in the ACF connections Xa to Xc by providing inspection terminals 96 and 97 on the control board 93, providing an inspection wiring line 98 that passes through the liquid crystal panel 91, the FPC 92, and the control board 93 and that connects the inspection terminals 96 and 97 to each other, and measuring a resistance value between the inspection terminals 96 and 97 in an inspection step prior to shipment is known.

Relating to the disclosure, Japanese Unexamined Patent Application Publication No. 2007-33742 discloses a liquid crystal display device that includes a liquid crystal panel having a plurality of common wirings, and that, in a self-diagnosis mode, determines a magnitude of a connection resistance between any two of the common wirings by outputting a diagnostic signal to one of the two common wirings and comparing the diagnostic signal with a signal appearing in the other of the two common wirings.

According to the method illustrated in FIG. 4, an initial abnormality of the ACF connections due to poor compression bonding or the like during manufacturing can be detected. However, in this method, an abnormality in the ACF connections that occurs during operation of the liquid crystal display device due to changes over time or the like cannot be detected.

### SUMMARY

Therefore, an object is to provide a display device that detects an abnormality in a connection using a film material which occurs during operation.

(1) A display device according to some embodiments of the disclosure includes a display panel, a flexible printed circuit board having a connection to the display panel by using a film material, a control board having a connection to the flexible printed circuit board by using the film material, and a semiconductor integrated circuit fixed on the display panel by using the film material and functioning as a drive circuit of the display panel, in which the semiconductor integrated circuit includes an inspection terminal, the display panel, the flexible printed circuit board, and the control board are provided with an inspection wiring line having one end connected to the inspection terminal and the other end to which a power supply voltage is applied on the control board, and the semiconductor integrated circuit includes a built-in resistor provided between the inspection terminal and a ground, a switching element provided in series with the built-in resistor between the inspection terminal and the ground, and an abnormality detection circuit that detects an abnormality in a resistance of the connections using the film material based on an output voltage of a resistance dividing circuit constituted by a resistance of the inspection wiring line and the built-in resistor.

In the above-described display device, the display panel, the flexible printed circuit board, the control board, and the semiconductor integrated circuit are connected by using the film material, the display panel, the flexible printed circuit board, and the control board are provided with the inspection wiring line, and the built-in resistor is provided in the semiconductor integrated circuit, and the power supply voltage is applied to the other end of the inspection wiring line. The abnormality detection circuit detects an abnormality in the resistance of the connections using the film material, based on the output voltage of the resistance dividing circuit constituted by the resistance of the inspection wiring line and the built-in resistor. Therefore, an abnormality in the connections using the film material which occurs during the operation of the display device can be detected by using the semiconductor integrated circuit that functions as the drive circuit of the display panel. Further, by providing the switching element in series with the built-in resistor, the bias current flowing through the inspection wiring line and the built-in resistor can be reduced, and thus the power consumption of the display device can be reduced, and excessive heat generation can be prevented.

(2) The display device according to some embodiments of the disclosure has the above-described configuration (1), and the display panel is a liquid crystal panel.

(3) The display device according to some embodiments of the disclosure has the above-described configuration (1), and the film material is an anisotropic conductive film.

(4) A display device according to some embodiments of the disclosure includes a display panel, a flexible printed circuit board having a connection to the display panel by using a film material, a control board having a connection to the flexible printed circuit board by using the film material, and a semiconductor integrated circuit fixed on the display panel by using the film material and functioning as a drive circuit of the display panel, in which the semiconductor integrated circuit includes a first inspection terminal and a second inspection terminal, the display panel, the flexible printed circuit board, and the control board are provided with a first inspection wiring line having one end connected to the first inspection terminal and the other end to which a power supply voltage is applied on the control board, and a second inspection wiring line having one end connected to the second inspection terminal and the other end to which the power supply voltage is applied on the control board, and the semiconductor integrated circuit includes a first built-in resistor provided between the first inspection terminal and a ground, a second built-in resistor provided between the second inspection terminal and the ground, and an abnormality detection circuit that detects an abnormality in a resistance of the connections using the film material based on an output voltage of a resistance dividing circuit constituted by a resistance of the first inspection wiring line and the first built-in resistor and on an output voltage of a resistance dividing circuit constituted by a resistance of the second inspection wiring line and the second built-in resistor.

According to the above-described display device, an abnormality in the connections using the film material which occurs during the operation of the display device can be detected by using the semiconductor integrated circuit that functions as the drive circuit of the display panel, as in the display panel having the above-described configuration (1). Further, by providing two inspection wiring lines in the display panel, the flexible printed circuit board, and the control board, and providing two built-in resistors in the semiconductor integrated circuit, thus detecting an abnormality in the resistance of a connection using the film material based on the output voltages of the two resistance dividing circuits, even if the resistance value of the built-in resistor varies, an abnormality in the resistance of a connection using the film material can be correctly detected.

(5) The display device according to some embodiments of the disclosure has the above-described configuration (4), and the semiconductor integrated circuit includes a first switching element provided in series with the first built-in resistor between the first inspection terminal and the ground and a second switching element provided in series with the second built-in resistor between the second inspection terminal and the ground.

(6) The display device according to some embodiments of the disclosure has the above-described configuration (4), the flexible printed circuit board has two sides extending in a direction connecting the display panel and the control board, the first inspection wiring line is provided along one of the two sides on the flexible printed circuit board, and the second inspection wiring line is provided along the other of the two sides on the flexible printed circuit board.

(7) The display device according to some embodiments of the disclosure has the above-described configuration (4), the semiconductor integrated circuit has two sides extending in a lateral direction, the first inspection terminal is provided at a position close to one of the two sides, and the second inspection terminal is provided at a position close to the other of the two sides.

(8) The display device according to some embodiments of the disclosure has the above-described configuration (4), and the display panel is a liquid crystal panel.

(9) The display device according to some embodiments of the disclosure has the above-described configuration (4), and the film material is an anisotropic conductive film.

These and other objects, features, aspects, and advantages of the disclosure will become more apparent from the following detailed description with reference to the accompanying drawings.

### BRIEF DESCRIPTION OF DRAWINGS

The disclosure will be described with reference to the accompanying drawings, wherein like numbers reference like elements.

FIG. 1 illustrates a configuration of a liquid crystal display device according to a first embodiment.

FIG. 2 illustrates a configuration of a liquid crystal display device according to a second embodiment.

FIG. 3 illustrates a configuration of a liquid crystal display device according to a third embodiment.

FIG. 4 illustrates a configuration of a known liquid crystal display device.

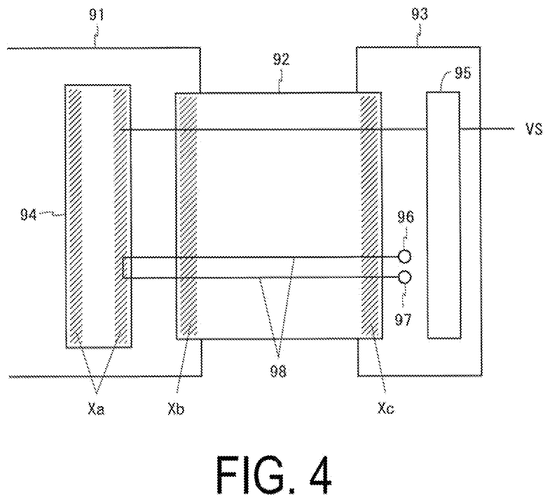

### DESCRIPTION OF EMBODIMENTS

### First Embodiment

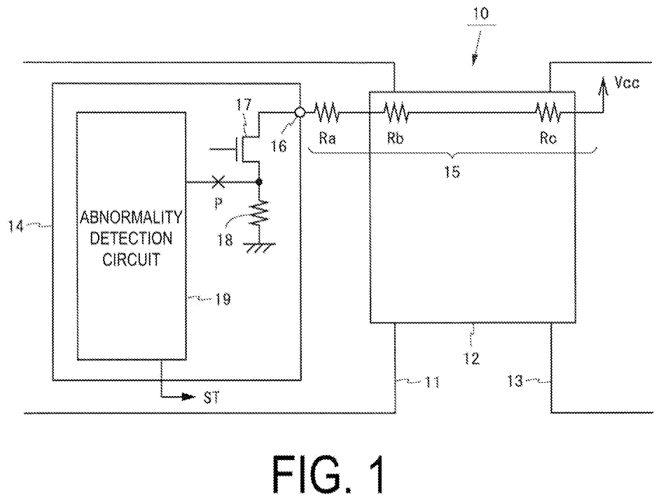

FIG. 1 illustrates a configuration of a liquid crystal display device according to a first embodiment. The liquid crystal display device 10 illustrated in FIG. 1 includes a liquid crystal panel 11, an FPC 12, a control board 13, and a drive circuit IC 14. The drive circuit IC 14 has an inspection terminal 16 and is mounted on the liquid crystal panel 11.

The liquid crystal panel 11 and the FPC 12 are connected to each other using an ACF. The FPC 12 and the control board 13 are also connected to each other using the ACF. The drive circuit IC 14 is fixed on the liquid crystal panel 11 using the ACF. The liquid crystal panel 11, the FPC 12, and the control board 13 are provided with an inspection wiring line 15. One end of the inspection wiring line 15 (the left end in FIG. 1) is connected to the inspection terminal 16. A power supply voltage Vcc is applied to the other end of the inspection wiring line 15 on the control board 13. The power supply voltage Vcc is, for example, 3.3 V.

Resistances Ra to Rc illustrated in FIG. 1 schematically illustrate resistances generated in the inspection wiring line 15 due to ACF connections. The resistance Ra is the resistance generated at a position where the liquid crystal panel 11 and the drive circuit IC 14 are connected by an ACF connection. The resistance Rb is the resistance generated at a position where the liquid crystal panel 11 and the FPC 12 are connected by an ACF connection. The resistance Rc is the resistance generated at a position where the FPC 12 and the control board 13 are connected by an ACF connection. As described above, the resistances Ra to Rc connected in series are generated in the inspection wiring line 15. Hereinafter, the resistances Ra to Rc are collectively referred to as “the resistance of the ACF connections”, and a resistance value of a combined resistance of the resistances Ra to Rc is referred to as R1.

The drive circuit IC 14 includes a switching element 17, a built-in resistor 18, and an abnormality detection circuit 19. The switching element 17 is, for example, a field effect transistor (FET). One end (the upper end in FIG. 1) of the switching element 17 is connected to the inspection terminal 16. The other end of the switching element 17 is connected to one end (the upper end in FIG. 1) of the built-in resistor 18. The other end of the built-in resistor 18 is grounded. As described above, the built-in resistor 18 is provided between the inspection terminal 16 and the ground, and the switching element 17 is provided in series with the built-in resistor 18 between the inspection terminal 16 and the ground. The resistance of the ACF connections and the built-in resistor 18 form a resistance dividing circuit that divides the power supply voltage Vcc.

The switching element 17 is turned on at a predetermined cycle. The switching element 17 is, for example, turned on for 10 ρs once per second. A node connected to the one end of the built-in resistor 18 is referred to as P, and a resistance value of the built-in resistor 18 is referred to as R0. When the switching element 17 is in an on state, a voltage Vp of the node P is given by the following equation (1). The following equation (2) is derived from the equation (1).

Vp=Vcc*R0/(R0+R1) (1)

R1=Vcc*R0/Vp−R0 (2)

The voltage Vp is an output voltage of the resistance dividing circuit when the power supply voltage Vcc is applied to the resistance dividing circuit constituted by the resistance of the ACF connections and the built-in resistor 18. The voltage Vp is input to the abnormality detection circuit 19.

When the switching element 17 is in the on state, the abnormality detection circuit 19 obtains the resistance value R1 using the equation (2) based on the voltage Vp, and determines whether or not the resistance of the ACF connections is abnormal based on the obtained resistance value R1. The abnormality detection circuit 19 determines that the resistance of the ACF connections is abnormal when the obtained resistance value R1 is equal to or more than a predetermined threshold value, and otherwise, determines that the resistance of the ACF connections is normal. The abnormality detection circuit 19 outputs a state signal ST indicating a result of the determination. For example, the state signal ST is at a low level when the resistance of the ACF connections is abnormal, and otherwise, is at a high level.

The state signal ST is output to the outside of the drive circuit IC 14, and is transmitted from the liquid crystal panel 11 via the FPC 12 and the control board 13 to a host device (not illustrated) connected to the control board 13 using measures not illustrated. This allows the host device to recognize an abnormality in the resistance of the ACF connections. Therefore, according to the liquid crystal display device 10, by using the drive circuit IC 14, an abnormality in the ACF connections that occurs during operation of the liquid crystal display device 10 can be detected.

The resistance value R1 becomes a value close to zero when the ACF connections are normal, and becomes larger than the value when the ACF connections are abnormal. However, even if an abnormality occurs in the ACF connections, the resistance value R1 may not become a very large value. For example, the resistance value R1 becomes about 1Ω when the ACF connections are normal, and becomes about 10Ω when a minor abnormality occurs in the ACF connections. Therefore, when the resistance value R0 of the built-in resistor 18 is increased (for example, when set to 1 kΩ), the abnormality detection circuit 19 may not accurately determine the resistance value R1 and may not correctly detect an abnormality in the resistance of the ACF connections. With regard to this point, it is preferable that the resistance value R0 be small.

However, when the resistance value R0 is reduced, a bias current flowing through the inspection wiring line 15 and the built-in resistor 18 increases. For example, when the power supply voltage Vcc is 3.3 V, the resistance value R0 is 10Ω, and the resistance value R1 when the ACF connections are normal is 1Ω, the bias current of 300 mA always flows through the inspection wiring line 15 and the built-in resistor 18. As a result, power consumption increases and excessive heat generation occurs.

The drive circuit IC 14 of the liquid crystal display device 10 includes the switching element 17 provided in series with the built-in resistor 18. The switching element 17 is turned on at the predetermined cycle, and the abnormality detection circuit 19 determines whether or not the resistance of the ACF connections is abnormal when the switching element 17 is in the on state. When the switching element 17 is in an off state, the bias current does not flow through the inspection wiring line 15 and the built-in resistor 18. Therefore, even when the resistance value R0 is reduced, the bias current flowing through the inspection wiring line 15 and the built-in resistor 18 can be reduced, and thus the power consumption of the liquid crystal display device 10 can be reduced, and excessive heat generation thereof can be prevented. For example, when the switching element 17 is turned on for 10 ρs once per second, the bias current flowing through the inspection wiring line 15 and the built-in resistor 18 is 1/100,000 of that when the switching element 17 is not provided.

As described above, the liquid crystal display device 10 according to the present embodiment includes a display panel (liquid crystal panel 11), a flexible printed circuit board (FPC 12) having a connection to the display panel by using a film material (ACF), the control board 13 having a connection to the flexible printed circuit board by using the film material, and a semiconductor integrated circuit (drive circuit IC 14) fixed on the display panel by using the film material and functioning as a drive circuit of the display panel. The semiconductor integrated circuit includes the inspection terminal 16, and the display panel, the flexible printed circuit board, and the control board 13 are provided with the inspection wiring line 15 having one end connected to the inspection terminal 16 and the other end to which the power supply voltage Vcc is applied on the control board 13. The semiconductor integrated circuit includes the built-in resistor 18 provided between the inspection terminal 16 and the ground, the switching element 17 provided in series with the built-in resistor 18 between the inspection terminal 16 and the ground, and the abnormality detection circuit 19 that detects an abnormality in the resistance of the connections using the film material (ACF connections) based on the output voltage (voltage Vp) of the resistance dividing circuit constituted by the resistance of the inspection wiring line 15 and the built-in resistor 18.

In the liquid crystal display device 10, the display panel, the flexible printed circuit board, the control board 13, and the semiconductor integrated circuit are connected by using the film material. In the liquid crystal display device 10, the display panel, the flexible printed circuit board, and the control board 13 are provided with the inspection wiring line 15. In the liquid crystal display device 10, the switching element 17 and the built-in resistor 18 are provided in the semiconductor integrated circuit, and the power supply voltage Vcc is applied to the other end of the inspection wiring line 15. The abnormality detection circuit 19 detects an abnormality in the resistance of the connections using the film material, based on the output voltage of the resistance dividing circuit constituted by the resistance of the inspection wiring line 15 and the built-in resistor 18. Therefore, according to the liquid crystal display device 10, the abnormality in the connections using the film material which occurs during the operation of the liquid crystal display device 10 can be detected by using the semiconductor integrated circuit that functions as the drive circuit of the display panel. Further, by providing the switching element 17 in series with the built-in resistor 18, the bias current flowing through the inspection wiring line 15 and the built-in resistor 18 can be reduced, and thus the power consumption of the liquid crystal display device 10 can be reduced, and excessive heat generation can be prevented.

In the liquid crystal display device 10, the switching element 17 is provided between the inspection terminal 16 and the built-in resistor 18, but the switching element 17 may be provided between the built-in resistor 18 and the ground. Therefore, even the liquid crystal display device according to this modification can obtain effects similar to those of the liquid crystal display device 10.

### Second Embodiment

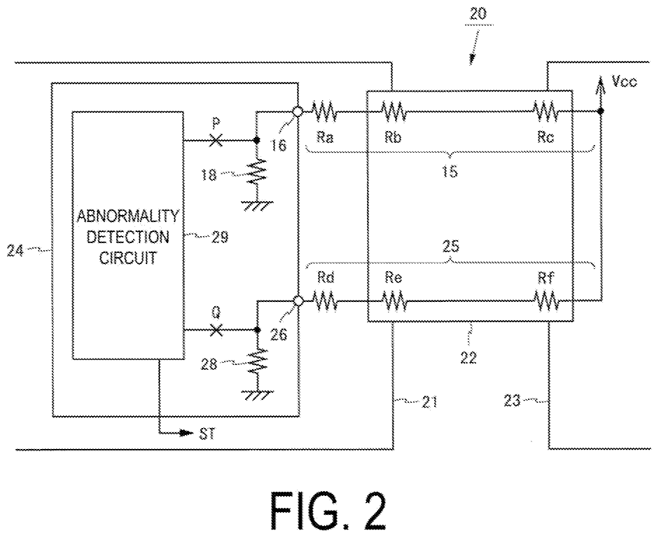

FIG. 2 illustrates a configuration of a liquid crystal display device according to a second embodiment. A liquid crystal display device 20 illustrated in FIG. 2 includes a liquid crystal panel 21, an FPC 22, a control board 23, and a drive circuit IC 24. The drive circuit IC 24 includes inspection terminals 16 and 26, and is mounted on the liquid crystal panel 21. The same constituent elements in the present embodiment as those in the first embodiment are denoted by the same reference signs, and the description thereof will be omitted.

The liquid crystal panel 21 and the FPC 22 are connected to each other by using the ACF. The FPC 22 and the control board 23 are also connected to each other by using the ACF. The drive circuit IC 24 is fixed on the liquid crystal panel 21 using the ACF. The liquid crystal panel 21, the FPC 22, and the control board 23 are provided with two inspection wiring lines 15 and 25. One end of the inspection wiring line 15 (the left end in FIG. 2) is connected to the inspection terminal 16. One end of the inspection wiring line 25 (the left end in FIG. 2) is connected to the inspection terminal 26. A power supply voltage Vcc is applied to the other ends of the inspection wiring lines 15 and 25 on the control board 23.

The FPC 22 has two sides extending in a direction connecting the liquid crystal panel 21 and the control board 23. The inspection wiring line 15 is provided along one of the two sides (the upper side in FIG. 2) on the FPC 22. The inspection wiring line 25 is provided along the other of the two sides (the lower side in FIG. 2) on the FPC 22. The drive circuit IC 24 has two sides extending in a lateral direction. The inspection terminal 16 is provided at a position close to one of the two sides (the upper side in FIG. 2). The inspection terminal 26 is provided at a position close to the other of the two sides (the lower side in FIG. 2). In this manner, the inspection wiring lines 15 and 25 are provided with an interval therebetween on the FPC 22, and the inspection terminals 16 and 26 are provided with an interval therebetween in the drive circuit 1C 24.

Resistances Ra to Rf illustrated in FIG. 2 schematically illustrate resistances generated at the inspection wiring lines 15 and 25 due to the ACF connections. Each of the resistances Ra and Rd is a resistance generated at a position where the liquid crystal panel 21 and the drive circuit IC 24 are connected by an ACF connection. Each of the resistances Rb and Re is a resistance generated at a position where the liquid crystal panel 21 and the FPC 22 are connected by an ACF connection. Each of the resistances Rc and Rf is a resistance generated at a position where the FPC 22 and the control board 23 are connected by an ACF connection. As described above, the resistances Ra to Rc connected in series are generated in the inspection wiring line 15, and the resistances Rd to Rf connected in series are generated in the inspection wiring line 25. Hereinafter, the resistances Ra to Rc are collectively referred to as “the resistance of a first ACF connection”, and a resistance value of a combined resistance of the resistances Ra to Rc is referred to as R1. The resistances Rd to Rf are collectively referred to as “the resistance of a second ACF connection”, and a resistance value of a combined resistance of the resistances Rd to Rf is referred to as R2.

The drive circuit IC 24 includes built-in resistors 18 and 28, and an abnormality detection circuit 29. One end (the upper end in FIG. 2) of the built-in resistor 18 is connected to the inspection terminal 16. One end (the upper end in FIG. 2) of the built-in resistor 28 is connected to the inspection terminal 26. The other ends of the built-in resistors 18 and 28 are grounded. The resistance values of the built-in resistors 18 and 28 are the same. As described above, the built-in resistor 18 is provided between the inspection terminal 16 and the ground, and the built-in resistor 28 is provided between the inspection terminal 26 and the ground. The first resistance of the ACF connection and the built-in resistor 18 form a resistance dividing circuit that divides the power supply voltage Vcc. The second resistance of the ACF connection and the built-in resistor 28 form another resistance dividing circuit that divides the power supply voltage Vcc.

A node connected to the one end of the built-in resistor 18 is referred to as P, a node connected to the one end of the built-in resistor 28 is referred to as Q, and the resistance values of the built-in resistors 18 and 28 are referred to as R0. A voltage Vp of the node P is given by the equation (1). The resistance value R1 is given by the equation (2). A voltage Vq of the node Q is given by the following equation (3). The following equation (4) is derived from the equation (3).

Vq=Vcc*R0/(R0+R2) (3)

R2=Vcc*R0/Vq−R0 (4)

The voltage Vp is an output voltage of the resistance dividing circuit when the power supply voltage Vcc is applied to the resistance dividing circuit constituted by the resistance of the first ACF connection and the built-in resistor 18. The voltage Vq is an output voltage of the resistance dividing circuit when the power supply voltage Vcc is applied to the other resistance dividing circuit constituted by the resistance of the second ACF connection and the built-in resistor 28. The voltages Vp and Vq are input to the abnormality detection circuit 29.

The abnormality detection circuit 29 obtains the resistance value R1 using the equation (2) based on the voltage Vp, obtains the resistance value R2 using the equation (4) based on the voltage Vq, and determines whether or not the resistance of the ACF connection is abnormal based on the obtained resistance values R1 and R2. The abnormality detection circuit 29 determines that the resistance of the first ACF connection or the second ACF connection is abnormal when a ratio of (or a difference between) the obtained resistance values R1 and R2 is equal to or more than a predetermined threshold value, and otherwise, determines that the resistances of the first ACF connection and the second ACF connection are normal. The abnormality detection circuit 29 outputs a state signal ST indicating a result of the determination.

Similar to the first embodiment, the state signal ST is transmitted to a host device (not illustrated). This allows the host device to recognize an abnormality in the resistance of the ACF connections. Therefore, according to the liquid crystal display device 20, by using the drive circuit IC 24, the abnormality in the ACF connection that occurs during operation of the liquid crystal display device 20 can be detected as in the first embodiment.

The built-in resistor of the drive circuit IC is formed by a photolithography process included in a manufacturing process of the semiconductor integrated circuit. The thickness of a thin film formed by the photolithography process tends to vary. As a result, the resistance value of the built-in resistor tends to vary between a plurality of the drive circuits IC. In the liquid crystal display device 10 according to the first embodiment, when the resistance value R0 of the built-in resistor 18 varies, the abnormality detection circuit 19 may not accurately determine the resistance value R1 and may not correctly detect an abnormality in the resistance of the ACF connections.

In the liquid crystal display device 20, the two inspection wiring lines 15 and 25 are provided in the liquid crystal panel 21, the FPC 22, and the control board 23, and the two built-in resistors 18 and 28 are provided in the drive circuit IC 24. In the liquid crystal display device 20, the abnormality detection circuit 29 detects an abnormality in the resistance of the ACF connections based on the two voltages Vp and Vq.

When a thin film is formed at two locations in one drive circuit IC in the photolithography process, the thicknesses of the two thin films are approximately the same. Further, the two thin films are formed to have approximately the same area. Therefore, even when the resistance value of the built-in resistor varies, the resistance values of the built-in resistors 18 and 28 are approximately the same.

When the first and second ACF connections are normal, the voltages Vp and Vq are the same, and thus the resistance values R1 and R2 obtained by the abnormality detection circuit 29 also are the same. The abnormality detection circuit 29 determines that the resistances of the first and second ACF connections are normal when the ratio of the resistance values R1 and R2 is close to 1 (or when the difference between the resistance values R1 and R2 is close to zero).

Generally, when an abnormality occurs in the first or second ACF connection, the resistance of either ACF connection becomes abnormal at first, rather than the resistances of both ACF connections becoming abnormal at the same time. When one of the first and second ACF connections becomes abnormal, the voltages Vp and Vq become different values, and thus the resistance values R1 and R2 obtained by the abnormality detection circuit 29 also become different values. The abnormality detection circuit 29 determines that the resistance of the first ACF connection or the second ACF connection is abnormal when the ratio of (or the difference between) the resistance values R1 and R2 is equal to or more than the predetermined threshold value. Therefore, even if the resistance value of the built-in resistor varies, an abnormality in the resistance of the ACF connections can be correctly detected.

As described above, the liquid crystal display device 20 according to the present embodiment includes a display panel (liquid crystal panel 21), a flexible printed circuit board (FPC 22) having a connection to the display panel using a film material (ACF), the control board 23 having a connection to the flexible printed circuit board using the film material, and a semiconductor integrated circuit (drive circuit IC 24) fixed on the display panel using the film material and functioning as a drive circuit of the display panel. The display panel, the flexible printed circuit board, and the control board 23 are provided with a first inspection wiring line (inspection wiring line 15) having one end connected to a first inspection terminal (inspection terminal 16) of the semiconductor integrated circuit and the other end to which a power supply voltage Vcc is applied on the control board 23, and a second inspection wiring line (inspection wiring line 25) having one end connected to a second inspection terminal (inspection terminal 26) of the semiconductor integrated circuit and the other end to which the power supply voltage Vcc is applied on the control board 23. The semiconductor integrated circuit includes a first built-in resistor (built-in resistor 18) provided between the first inspection terminal and the ground, a second built-in resistor (built-in resistor 28) provided between the second inspection terminal and the ground, and the abnormality detection circuit 29 that detects an abnormality in the resistance of the connections using the film material (ACF connections) based on the output voltage (voltage Vp) of the resistance dividing circuit constituted by the resistance of the first inspection wiring line and the first built-in resistor and on the output voltage (voltage Vq) of the resistance dividing circuit constituted by the resistance of the second inspection wiring line and the second built-in resistor.

As in the first embodiment, according to the liquid crystal display device 20, an abnormality in the connections using the film material which occurs during the operation of the liquid crystal display device 20 can be detected by using the semiconductor integrated circuit that functions as a drive circuit of the display panel. Further, by providing two inspection wiring lines in the display panel, the flexible printed circuit board, and the control board 23, and detecting an abnormality in the resistance of a connection using the film material based on the output voltages of the two resistance dividing circuits, even if the resistance value of the built-in resistor varies, an abnormality in the resistance of the ACF connections can be correctly detected.

The flexible printed circuit board has two sides extending in a direction connecting the display panel and the control board 23, the first inspection wiring line is provided along one of the two sides on the flexible printed circuit board, and the second inspection wiring line is provided along the other of the two sides on the flexible printed circuit board. The semiconductor integrated circuit has two sides extending in a lateral direction. The first inspection terminal is provided at a position close to one of the two sides, and the second inspection terminal is provided at a position close to the other of the two sides. When two inspection wiring lines (or two inspection terminals) are provided with an interval therebetween in this manner, a difference is more likely to occur between the resistance value R1 of the resistance of the first ACF connection and the resistance value R2 of the resistance of the second ACF connection. Therefore, an abnormality in the resistance of the ACF connections can be detected early.

### Third Embodiment

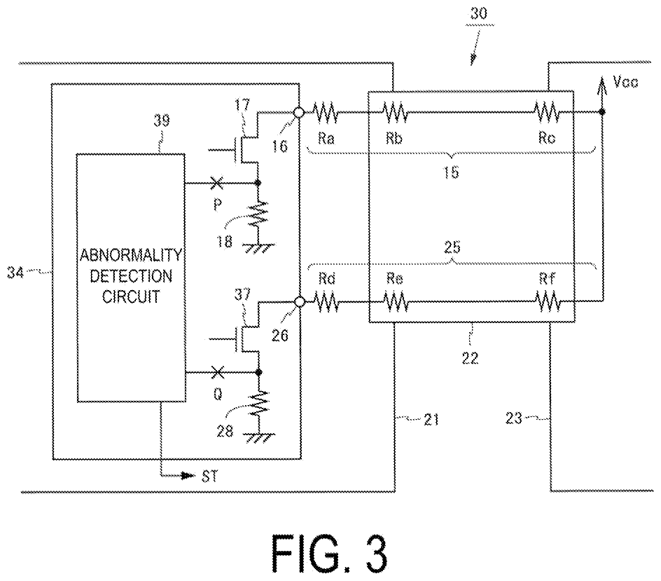

FIG. 3 illustrates a configuration of a liquid crystal display device according to a third embodiment. A liquid crystal display device 30 illustrated in FIG. 3 has a configuration in which the drive circuit IC 24 in the liquid crystal display device 20 according to the second embodiment is replaced with a drive circuit IC 34. Note that elements common to those in the first and second embodiments are denoted by the same reference signs, and duplicated description thereof will be omitted.

The drive circuit IC 34 includes inspection terminals 16 and 26, and is mounted on a liquid crystal panel 21. The drive circuit IC 34 includes switching elements 17 and 37, built-in resistors 18 and 28, and an abnormality detection circuit 39. The switching elements 17 and 37 are, for example, field effect transistors.

Similar to the first embodiment, one end (the upper end in FIG. 3) of the switching element 17 is connected to the inspection terminal 16. The other end of the switching element 17 is connected to one end (a node P) of the built-in resistor 18. One end (upper end in FIG. 3) of the switching element 37 is connected to the inspection terminal 26. The other end of the switching element 37 is connected to one end (a node Q) of the built-in resistor 28. As described above, the built-in resistor 18 is provided between the inspection terminal 16 and the ground, and the switching element 17 is provided in series with the built-in resistor 18 between the inspection terminal 16 and the ground. The built-in resistor 28 is provided between the inspection terminal 26 and the ground, and the switching element 37 is provided in series with the built-in resistor 28 between the inspection terminal 26 and the ground.

When the switching element 17 is in an on state, a voltage Vp of the node P is given by the equation (1), and a resistance value R1 is given by the equation (2). The switching element 37 is turned on at the same timing as the switching element 17. When the switching element 37 is in an on state, a voltage Vq of the node Q is given by the equation (3), and a resistance value R2 is given by the equation (4). The voltages Vp and Vq are input to an abnormality detection circuit 39.

When the switching elements 17 and 37 are in the on state, the abnormality detection circuit 39 obtains the resistance value R1 using the equation (2) based on the voltage Vp, obtains the resistance value R2 using the equation (4) based on the voltage Vq, and determines whether or not the resistance of the ACF connections is abnormal based on the obtained resistance values R1 and R2. The abnormality detection circuit 39 outputs a state signal ST indicating a result of the determination.

Similar to the first and second embodiments, a state signal ST is transmitted to a host device (not illustrated). This allows the host device to recognize an abnormality in the resistance of the ACF connections. Therefore, according to the liquid crystal display device 30, by using the drive circuit IC 34, an abnormality in the ACF connections which occurs during operation of the liquid crystal display device 30 can be detected as in the first and second embodiments.

Further, according to the liquid crystal display device 30, even if the resistance value of the built-in resistor varies, an abnormality in the resistance of the ACF connections can be correctly detected as in the second embodiment. Furthermore, as in the first embodiment, the bias current flowing through the inspection wiring line and the built-in resistor can be reduced, and thus the power consumption of the liquid crystal display device 30 can be reduced, and excessive heat generation thereof can be prevented.

As described above, in the liquid crystal display device 30 according to the present embodiment, a semiconductor integrated circuit (drive circuit IC 34) includes a first switching element (switching element 17) provided in series with a first built-in resistor (built-in resistor 18) between a first inspection terminal (inspection terminal 16) and the ground, and a second switching element (switching element 37) provided in series with a second built-in resistor (built-in resistor 28) between a second inspection terminal (inspection terminal 26) and the ground.

According to the liquid crystal display device 30, the same effects as those of the second embodiment can be obtained. In addition, by providing the first and second switching elements, the bias currents flowing through the first inspection wiring line and the first built-in resistor and through the second inspection wiring line and the second built-in resistor can be reduced, and thus the power consumption of the liquid crystal display device 30 can be reduced, and excessive heat generation can be prevented.

In the liquid crystal display device 30, the switching element 17 is provided between the inspection terminal 16 and the built-in resistor 18, and the switching element 37 is provided between the inspection terminal 26 and the built-in resistor 28. However, the switching element 17 may be provided between the built-in resistor 18 and the ground and the switching element 37 may be provided between the built-in resistor 28 and the ground. The liquid crystal display device according to this modification can also obtain effects similar to those of the liquid crystal display device 30.

Although a liquid crystal display device including a liquid crystal panel has been described so far, a display device other than a liquid crystal display device including a display panel other than a liquid crystal panel can be formed in the same manner.

Although the disclosure has been described in detail above, the above description is exemplary in all respects and is not limiting. It is understood that numerous other modifications or variations can be made without departing from the scope of the disclosure.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

1. A display device comprising:
a display panel;
a flexible printed circuit board having a connection to the display panel by using a film material;
a control board having a connection to the flexible printed circuit board by using the film material; and
a semiconductor integrated circuit fixed on the display panel by using the film material and functioning as a drive circuit of the display panel,
wherein the semiconductor integrated circuit includes an inspection terminal;
the display panel, the flexible printed circuit board, and the control board are provided with an inspection wiring line having one end connected to the inspection terminal and the other end to which a power supply voltage is applied on the control board; and
the semiconductor integrated circuit includes a built-in resistor provided between the inspection terminal and a ground, a switching element provided in series with the built-in resistor between the inspection terminal and the ground, and an abnormality detection circuit that detects an abnormality in a resistance of the connections using the film material based on an output voltage of a resistance dividing circuit constituted by a resistance of the inspection wiring line and the built-in resistor.

2. The display device according to claim 1,
wherein the display panel is a liquid crystal panel.

3. The display device according to claim 1,
wherein the film material is an anisotropic conductive film.

4. A display device comprising:
a display panel;
a flexible printed circuit board having a connection to the display panel by using a film material;
a control board having a connection to the flexible printed circuit board by using the film material; and
a semiconductor integrated circuit fixed on the display panel by using the film material and functioning as a drive circuit of the display panel,
wherein the semiconductor integrated circuit includes a first inspection terminal and a second inspection terminal;
the display panel, the flexible printed circuit board, and the control board are provided with a first inspection wiring line having one end connected to the first inspection terminal and the other end to which a power supply voltage is applied on the control board, and a second inspection wiring line having one end connected to the second inspection terminal and the other end to which the power supply voltage is applied on the control board; and
the semiconductor integrated circuit includes a first built-in resistor provided between the first inspection terminal and a ground, a second built-in resistor provided between the second inspection terminal and the ground, and an abnormality detection circuit that detects an abnormality in a resistance of the connections using the film material based on an output voltage of a resistance dividing circuit constituted by a resistance of the first inspection wiring line and the first built-in resistor and on an output voltage of a resistance dividing circuit constituted by a resistance of the second inspection wiring line and the second built-in resistor.

5. The display device according to claim 4,
wherein the semiconductor integrated circuit includes a first switching element provided in series with the first built-in resistor between the first inspection terminal and the ground and a second switching element provided in series with the second built-in resistor between the second inspection terminal and the ground.

6. The display device according to claim 4,
wherein the flexible printed circuit board has two sides extending in a direction connecting the display panel and the control board,
the first inspection wiring line is provided along one of the two sides on the flexible printed circuit board, and
the second inspection wiring line is provided along the other of the two sides on the flexible printed circuit board.

7. The display device according to claim 4,
wherein the semiconductor integrated circuit has two sides extending in a lateral direction,
the first inspection terminal is provided at a position close to one of the two sides, and
the second inspection terminal is provided at a position close to the other of the two sides.

8. The display device according to claim 4,
wherein the display panel is a liquid crystal panel.

9. The display device according to claim 4,
wherein the film material is an anisotropic conductive film.
